(19) United States
(12) Patent Application Publication
(10) Pub. No.: US 2016/0276397 A1
(43) Pub. Date: Sep. 22, 2016

(54) SOLID-STATE IMAGING DEVICE AND MANUFACTURING METHOD THEREFOR

(71) Applicant: Kabushiki Kaisha Toshiba, Minato-ku (JP)

(72) Inventor: Kenichi ARAKAWA, Fujisawa (JP)

(73) Assignee: Kabushiki Kaisha Toshiba, Minato-ku (JP)

(21) Appl. No.: 14/844,164

(22) Filed: Sep. 3, 2015

(30) Foreign Application Priority Data
Mar. 16, 2015 (JP) 2015-052394

(51) Int. Cl. H01L 27/146

(52) U.S. Cl. CPC H01L 27/14645; H01L 27/14627; H01L 27/14607; H01L 27/14621; H01L 27/14685

(57) ABSTRACT

A solid-state imaging device according to an embodiment includes a first semiconductor layer of a first conductivity type, a photodiode region in which a second semiconductor layer of a second conductivity type is formed in a surface of the first semiconductor layer, a first interlayer insulating film which is formed on the first semiconductor layer and on the photodiode region, a first fixed charge film which is formed on the first interlayer insulating film and has a charge of the second conductivity type, a second interlayer insulating film which is formed on or above the first fixed charge film, and a second fixed charge film which is formed on the second interlayer insulating film and has a charge of the second conductivity type.

### CROSS REFERENCE TO RELATED APPLICATION

This application is based upon and claims the benefit of priority from the prior Japanese Patent Applications No. 2015-52394, filed on Mar. 16, 2015; the entire contents of which are incorporated herein by reference,

### FIELD

Embodiments described herein relate generally to a solid-state imaging device and a manufacturing method for the solid-state imaging device.

### BACKGROUND

Various solid-state imaging devices, such as a CMOS image sensor which is manufactured using a semiconductor process, have been developed in recent years. In such a solid-state imaging device, a light-receiving section is formed at each of pixels arrayed in a two-dimensional array. The light-receiving section at each pixel has a photodiode region which is composed of, e.g., an N-type semiconductor layer formed in a P-type silicon layer. Light incident on the light-receiving section at each pixel causes charges corresponding to the amount of incident light to be accumulated in the photodiode region.

An interlayer insulating film is formed on the P-type silicon layer, and, for example, a wiring layer and a contact region are formed on the interlayer insulating film. A protective film is formed on the interlayer insulating film, the wiring layer, and the contact region, and a planarization film is formed on the protective film. Color filter layers are formed on the planarization film, and microlenses are arranged on the color filters. At each pixel, incident light is condensed on the light-receiving section. The color filters transmit, for example, R (red), G (green), and B (blue) light beams and make the light beams incident on the light-receiving sections at the respective pixels. A plurality of pixels on which different color light beams are incident detect color components, thus achieving colorization.

An interface between each photodiode region in the silicon layer and the interlayer insulating film (hereinafter referred to as a PD interface) is depleted when a voltage is applied to the photodiode region. A leak current (dark current) is likely to flow under an influence of an interface state of the PD interface caused by discontinuity between the silicon layer and the interlayer insulating film. A method involving forming a fixed charge film with negative polarity on the interlayer insulating film may be adopted to inhibit production of such a dark current. The depletion at the PD interface is prevented by attracting holes in the silicon layer to the PD interface by the fixed charge film and filling the PD interface with the holes, which inhibits production of a dark current.

The PD interface, however, may be charged in a step regarding a surface of the solid-state imaging device, such as a dicing step, an assembly step, or the like during a semiconductor process. Even after shipping, if the PD interface is, for example, positively charged, a negative field of the fixed charge film is neutralized, action of the negative field of the fixed charge film on the PD interface becomes weak, and holes become unlikely to be guided to the PD interface. Thus, a hole density at the PD interface decreases, the PD interface is locally depleted, and inhibition of a dark current becomes difficult.

The protective film has a property of being charged with part of an applied voltage, for example, if a relative high voltage caused by static electricity is applied to the protective film. For example, if an abruptly changing positive voltage is applied to the protective film, positive charges are held on the protective film even after shipping. When an electric field produced by the charges held on the protective film cancels out an electric field of the fixed charge film, hole-guiding action of the fixed charge film on the PD interface is inhibited, and the PD interface is depleted, which causes dark current unevenness.

### BRIEF DESCRIPTION OF THE DRAWINGS

FIG. 1 is an explanatory view for explaining an outline of a cross-sectional shape of a solid-state imaging device according to a first embodiment;

FIG. 2 is a flowchart showing a manufacturing method for the solid-state imaging device according to the first embodiment;

FIG. 3 is a chart showing a relationship between a fixed charge film thickness and white spot production;

FIGS. 4A and 4B are explanatory views for explaining an effect of inhibiting a dark current according to the present embodiment;

FIG. 5 is an explanatory view for explaining an outline of a cross-sectional shape of a solid-state imaging device according to a second embodiment of the present invention; and

FIG. 6 is an explanatory view for explaining an effect of inhibiting a dark current according to the second embodiment.

### DETAILED DESCRIPTION

A solid-state imaging device according to an embodiment includes a first semiconductor layer of a first conductivity type, a photodiode region in which a second semiconductor layer of a second conductivity type is formed in a surface of the first semiconductor layer, a first interlayer insulating film which is formed on the first semiconductor layer and on the photodiode region, a first fixed charge film which is formed on the first interlayer insulating film and has a charge of the second conductivity type, a second interlayer insulating film which is formed on or above the first fixed charge film, and a second fixed charge film which is formed on the second interlayer insulating film and has a charge of the second conductivity type.

Embodiments of the present invention will be described below in detail with reference to the drawings.

### First Embodiment

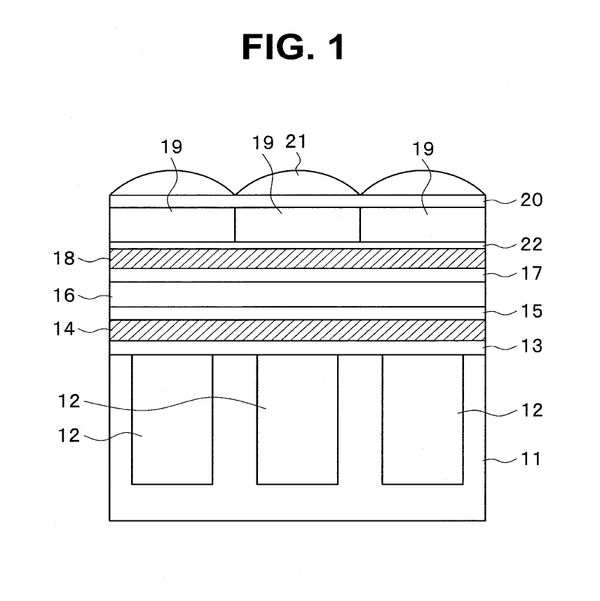

FIG. 1 is an explanatory view for explaining an outline of a cross-sectional shape of a solid-state imaging device according to a first embodiment.

The solid-state imaging device according to the embodiment is composed of a plurality of pixels arrayed in a matrix. Each pixel includes a photodiode. The pixel accumulates charges obtained through photoelectric conversion of incident light and outputs a pixel signal with a level based on the accumulated charges. Since the individual pixels are arrayed in a matrix, image signals for one screen are obtained.

FIG. 1 is intended to explain a cross-sectional shape of each pixel and shows a configuration of three adjacent pixels. Although the embodiment illustrates an example where an electron is used as a charge, a positive hole may also be used as a charge. Note that a wiring layer, a contact layer, a contact hole, a light-shielding film, and the like are not shown in FIG. 1.

In a P-type silicon layer 11, a photodiode region 12, in which an N-type semiconductor layer is formed, is formed for each pixel. The photodiode region 12 is formed from a surface of the silicon layer 11 to a predetermined depth. Each photodiode region 12 has a function of accumulating charges (electrons in the embodiment) for the corresponding pixel in the N-type semiconductor layer. An interlayer insulating film 13 is formed all over surfaces of the photodiode regions 12 and the surface of the silicon layer 11.

In the embodiment, a first fixed charge film 14 (a shaded portion) with negative fixed charges is formed all over the interlayer insulating film 13. In the embodiment, an interlayer insulating film 15, a protective film 16, and an interlayer insulating film 17 are further stacked on the first fixed charge film 14. A second fixed charge film 18 (a shaded portion) with negative fixed charges is formed all over the interlayer insulating film 17.

After an interlayer insulating film 22 of SiO₂ or the like is formed on the second fixed charge film 18, color filter layers 19 are formed. The color filter layers 19 correspond to respective pixels and are colored in, for example, red (R), green (G), and blue (B). Microlenses 21 are formed above the color filter layers 19 with a planarization layer 20 between the microlenses 21 and the color filter layers 19. With the microlenses 21 and the color filter layers 19, color light beams from an object are incident on individual pixels.

As will be described later, the second fixed charge film 18 has a function of inhibiting production of a dark current caused especially by surface charge-up or the like, like the first fixed charge film 14.

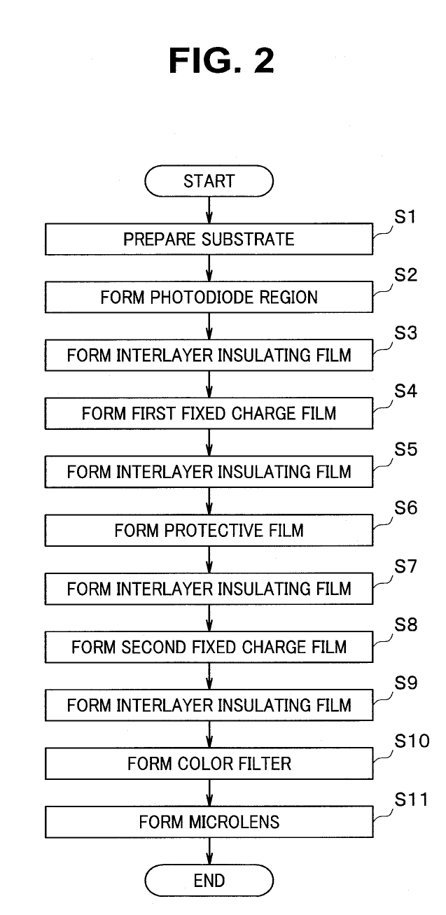

A manufacturing method for the solid-state imaging device in FIG. 1 will be described with reference to FIG. 2. FIG. 2 is a flowchart showing the manufacturing method for the solid-state imaging device according to the first embodiment.

A P-type silicon substrate to serve as the silicon layer 11 is first prepared (step S1). A photodiode region 12 is formed in each of pixel regions through, for example, ion implantation (step S2). Note that the silicon layer 11 may be formed as a semiconductor layer, such as a well, and a photodiode region may be formed in the semiconductor layer, instead of directly forming a photodiode region in a semiconductor substrate. For example, the photodiode region 12 is formed by forming an N-type semiconductor layer to a predetermined position of the silicon layer 11 through implantation of ions of phosphorus or the like. In step S3, the interlayer insulating film 13 of an SiO₂ (silicon oxide) film or the like is formed on the entire surface of the silicon layer 11 and an entire surface of each photodiode region 12 through CVD (chemical vapor deposition), ALD (atomic layer deposition), or the like.

In step S4, the first fixed charge film 14 with negative fixed charges is formed on a surface of the interlayer insulating film 13 through CVD, ALD, or the like. For example, hafnium oxide (HfO₂) or tantalum oxide (Ta₂O₅) is adopted as a material for the first fixed charge film 14.

In step S5, the interlayer insulating film 15 of an SiO₂ film or the like is formed on a surface of the first fixed charge film 14 through, for example, CVD or ALD. In step S6, the protective film 16 of an SiN (silicon nitride) film or the like is formed on a surface of the interlayer insulating film 15 through, for example, CVD or ALD. Note that the protective film 16 has an effect of trapping hydrogen to inhibit production of a dark current. In step S7, the interlayer insulating film 17 of an SiO₂ film or the like is formed on a surface of the protective film 16 through, for example, CVD or ALD.

In the embodiment, in next step S8, the second fixed charge film 18 with negative fixed charges is formed on a surface of the interlayer insulating film 17 through, for example, CVD or ALD. For example, hafnium oxide (HfO₂) or tantalum oxide (Ta₂O₅) is adopted as a material for the second fixed charge film 18.

In step S9, the interlayer insulating film 22 of SiO₂ or the like is formed on the second fixed charge film 18 through, for example, CVD or ALD. The interlayer insulating film 22 is provided in order to prevent charges from coming out from the second fixed charge film 18. In step S10, the color filter layers 19 are formed by exposing color resists to light with a predetermined pattern. In step S11, the planarization layer 20 is formed on the color filter layers 19. After the formation, the microlenses 21 are formed.

### (Action)

In the solid-stage image pickup device with the above-described configuration, the first and second fixed charge films 14 and 18 can ensure inhibition of production of a dark current, regardless of presence or absence of surface charge-up or the like.

As an approach to enhancement of an effect of inhibiting a dark current, increasing thickness of a fixed charge film with negative fixed charges is conceivable. Stacking a plurality of fixed charge films to increase a fixed charge film thickness is also conceivable. An effect of inhibiting production of a white spot or the like due to a dark current cannot be improved only by increasing a fixed charge film thickness.

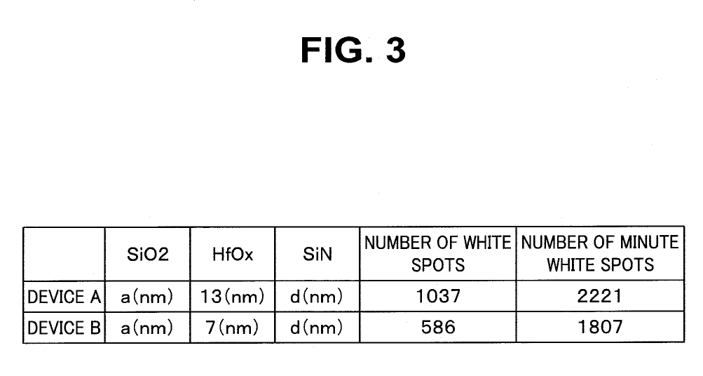

FIG. 3 is a chart showing a relationship between a fixed charge film thickness and white spot production. Note that FIG. 3 shows the number of white spots produced when 2.8 V was applied as a power supply voltage.

An a(nm)-thick SiO₂ film which is an interlayer insulating film is formed on each of respective substrates for a device A and a device B. In the device A, an HfOₓ film which has a thickness of 13 nm and is a fixed charge film is formed on the SiO₂ film. In the device B, an HfOₓ film which has a thickness of 7 nm and is a fixed charge film is formed on the SiO₂ film. In either of the devices A and B, an SiN film which is a d(nm)-thick protective film is formed on the HfOₓ film.

As shown in FIG. 3, thicknesses of the SiO₂ films are equal to each other, and thicknesses of the SiN films are also equal to each other. The devices A and B, however, have the HfOₓ films different in thickness as the fixed charge films. The thickness of 7 nm in the device B is smaller than the thickness of 13 nm in the device A. FIG. 3 shows that the number of white spots produced in the device A with the larger fixed charge film thickness was 1,037, and the number of minute white spots was 2,221 while the number of white spots produced in the device B with the smaller fixed charge film thickness was 586, and the number of minute white spots was 1,807.

Production of a white spot is thought to be due to a dark current. As described above, the examples of the devices A and B show that a dark current which may cause a white spot cannot be inhibited only by increasing a fixed charge film thickness. For the reason, in the embodiment, a fixed charge film is constructed as two layers instead of simply increasing a film thickness, and an interlayer insulating film of a silicon oxide film, a silicon nitride film, or the like is arranged between the layers as the fixed charge film. The configuration allows inhibition of surface charge-up, prevention of depletion of a photodiode interface, and inhibition of a dark current.

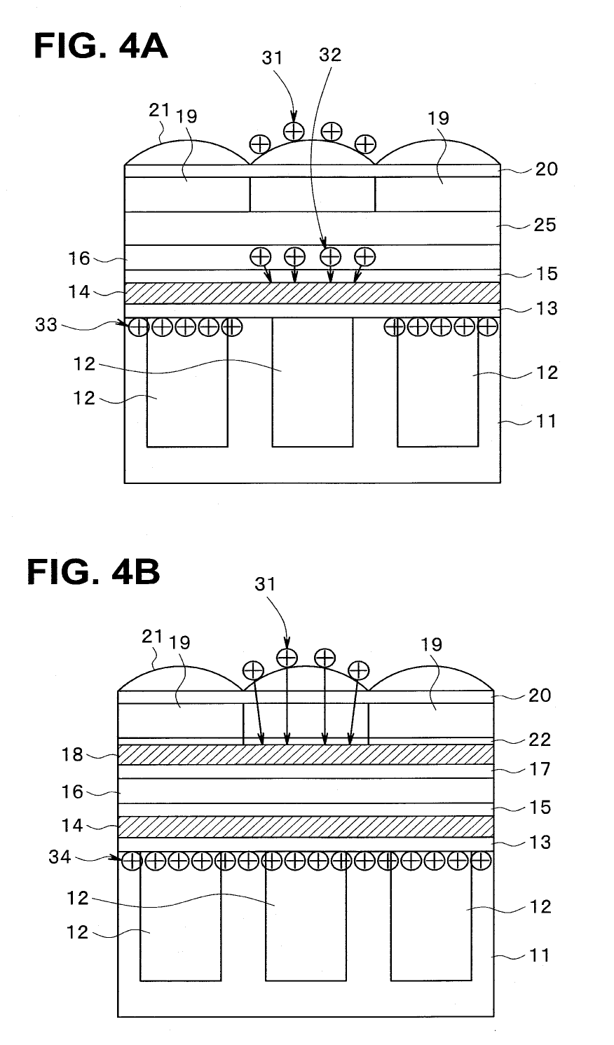

FIGS. 4A and 4B are explanatory views for explaining an effect of inhibiting a dark current according to the embodiment. FIG. 4A is intended to explain a reason why a dark current is produced in related art. FIG. 4B is intended to explain a reason why the first embodiment can inhibit production of a dark current.

FIG. 4A shows a solid-state imaging device according to the related art. An interlayer insulating film 25 is formed instead of the interlayer insulating film 17 and the second fixed charge film 18 of the solid-state imaging device according to the first embodiment shown in FIG. 4B. The solid-state imaging device in FIG. 4A is configured such that the first fixed charge film 14 attracts holes 33 from the silicon layer 11 to a PD interface. However, during manufacture or at other times, a surface of the solid-state imaging device may be charged with positive charges 31 to cause surface charge-up, and positive charges 32 may be trapped in the protective film 16. The positive charges 31 and 32 act on the first fixed charge film 14 to partially neutralize negative charges of the first fixed charge film 14. A portion with neutralized charges of the first fixed charge film 14 has no longer an effect of attracting holes to the PD interface. As shown in FIG. 4A, a region without the holes 33 appears at a part of the PD interface. That is, the region may be depleted to produce a dark current.

In contrast, in the solid-state imaging device according to the embodiment, the second fixed charge film 18 is formed above the first fixed charge film 14 with the interlayer insulating film 15, the protective film 16, and the interlayer insulating film 17 interposed between the second fixed charge film 18 and the first fixed charge film 14. The second fixed charge film 18 not only has a function of trapping the positive charges 31 formed during manufacture or at other times but also is capable of inhibiting production of positive charges at the protective film 16. The second fixed charge film 18 prevents the first fixed charge film 14 from being neutralized by the positive charges 31 and 32. As described above, the first fixed charge film 14 according to the embodiment has an effect of attracting holes 34 all over a PD interface. The effect prevents depletion throughout the PD interface and inhibits production of a dark current. In the embodiment, the second fixed charge film 18 is formed between the color filter layers 19 near a surface and the interlayer insulating film 17 in order to trap the positive charges 31 and 32 that are produced near the surface. A position where the second fixed charge film 18 is formed, however, is not limited to a position in the embodiment. A stronger effect can be obtained by forming the second fixed charge film 18 at a position near produced positive charges.

As described above, the first and second fixed charge films 14 and 18 are provided with the interlayer insulating film 15, the protective film 16, and the interlayer insulating film 17 interposed between the first fixed charge film 14 and the second fixed charge film 18. An effect of trapping the positive charges 31 and 32 can be improved, and prevention of depletion of the PD interface can be ensured, as compared to a case where thickness of the first fixed charge film 14 is simply increased. Since a fixed charge film is sandwiched between interlayer insulating films of SiO₂ or the like to allow an electric field of the fixed charge film to be kept, as in the embodiment, more positive charges can be trapped.

Note that an example where three layers of the interlayer insulating film 15, the protective film 16, and the interlayer insulating film 17 are interposed between the first and second fixed charge films 14 and 18 has been described with reference to FIG. 1. The present invention, however, is not limited to three layers. Same effects are assumed to be obtained by interposing one or a plurality of interlayer insulating films (a protective film is also an interlayer insulating film in a general sense).

As described above, in the present embodiment, a first fixed charge film is formed in order to block depletion of a PD interface and inhibit production of a dark current. In view of the fact that an effect of inhibiting a white spot cannot be improved only by increasing a thickness of the first fixed charge film, a second fixed charge film is formed on or above the first fixed charge film with one or a plurality of interlayer insulating films between the second and first fixed charge films, and the second fixed charge film traps charges due to surface charge-up or the like. With the configuration, the first fixed charge film ensures blockage of depletion and inhibits production of a dark current. It is thus possible to inhibit production of a white spot or the like and obtain a high-quality image pickup image.

### Second Embodiment

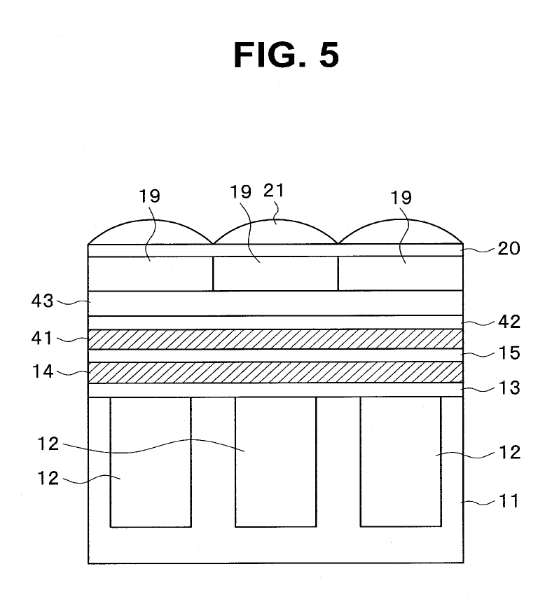

FIG. 5 is an explanatory view for explaining an outline of a cross-sectional shape of a solid-state imaging device according to a second embodiment of the present invention. Components in FIG. 5 identical to the components in FIG. 1 are denoted by identical reference numerals, and a description of the components will be omitted.

The solid-state imaging device according to the embodiment is different from the solid-state imaging device according to the first embodiment in that a second fixed charge film 41 (a shaded portion), an interlayer insulating film 42, and a protective film 43 are formed instead of the protective film 16, the interlayer insulating film 17, and the second fixed charge film 18 in FIG. 1.

That is, in the embodiment, the second fixed charge film 41 is formed above a first fixed charge film 14 with an interlayer insulating film 15 between the second fixed charge film 41 and the first fixed charge film 14. The interlayer insulating film 42 and the protective film 43 are stacked on the second fixed charge film 41, and color filter layers 19 are formed on the protective film 43. The protective film 43 has a function of a planarization film and has an effect of trapping hydrogen to inhibit production of a dark current.

In the embodiment, the second fixed charge film 41 has a function of inhibiting production of a dark current due to surface charge-up or the like.

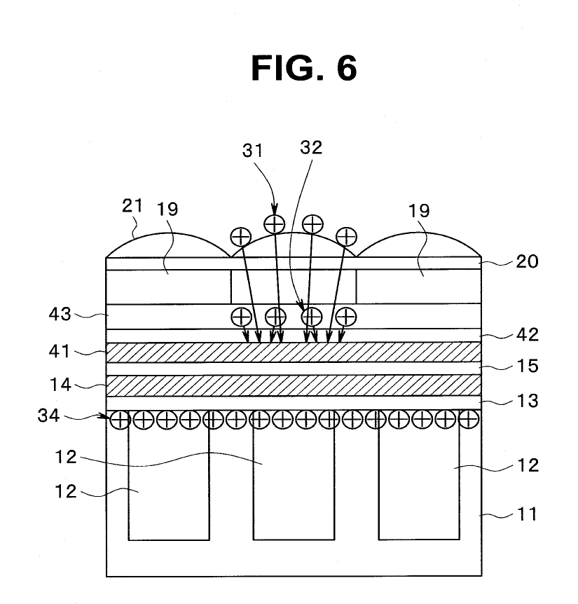

Action of the embodiment with the above-described configuration will be described with reference to FIG. 6. FIG. 6 is an explanatory view for explaining an effect of inhibiting a dark current according to the second embodiment.

In the embodiment, the first and second fixed charge films 14 and 41 can ensure inhibition of production of a dark current, regardless of presence or absence of surface charge-up or the like. In the solid-state imaging device according to the embodiment, the second fixed charge film 41 is formed above the first fixed charge film 14 with the interlayer insulating film 15 interposed between the second and first fixed charge films 41 and 14. The second fixed charge film 41 has a function of trapping positive charges 31 and 32 formed during manufacture or at other times. The function prevents the first fixed charge film 14 from being neutralized by the positive charges 31 and 32. As described above, the first fixed charge film 14 according to the embodiment has an effect of attracting holes 34 all over a PD interface. It is thus possible to prevent depletion throughout the PD interface and inhibit production of a dark current.

As described above, the second embodiment can obtain same effects as the effects of the first embodiment.

The above-described embodiments have been described in a context of a so-called N-type photodiode which accumulates electrons due to a photoelectric effect. Effects of the embodiments can be obtained by use of a fixed charge film with positive polarity in a case of a P-type photodiode which accumulates holes.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A solid-state imaging device comprising:
a first semiconductor layer of a first conductivity type;
a photodiode region in which a second semiconductor layer of a second conductivity type is formed in a surface of the first semiconductor layer;
a first interlayer insulating film which is formed on the first semiconductor layer and on the photodiode region;
a first fixed charge film which is formed on the first interlayer insulating film and has a charge of the second conductivity type;
a second interlayer insulating film which is formed on or above the first fixed charge film; and
a second fixed charge film which is formed on the second interlayer insulating film and has a charge of the second conductivity type.

2. The solid-state imaging device according to claim 1, wherein
the second interlayer insulating film includes an insulating film which contains nitrogen.

3. The solid-state imaging device according to claim 1, further comprising:
a third interlayer insulating film which is formed on or above the second fixed charge film; and
a filter layer and a microlens which are formed on or above the third interlayer insulating film.

4. The solid-state imaging device according to claim 1, wherein
the first and second fixed charge films are each sandwiched between insulating films which each include a silicon oxide film.

5. A manufacturing method for a solid-state imaging device, comprising:
forming a photodiode region in which a second semiconductor layer of a second conductivity type is formed in a surface of a first semiconductor layer of a first conductivity type;
forming a first interlayer insulating film on the first semiconductor layer and on the photodiode region;
forming a first fixed charge film which has a charge of the second conductivity type on the first interlayer insulating film;
forming a second interlayer insulating film on or above the first fixed charge film; and
forming a second fixed charge film which has a charge of the second conductivity type on the second interlayer insulating film.

6. The manufacturing method for the solid-state imaging device according to claim 5, wherein
the second interlayer insulating film forms a plurality of layers which comprise a plurality of insulating films.

7. The manufacturing method for the solid-state imaging device according to claim 5, wherein
the second interlayer insulating film includes an insulating film which contains nitrogen.

8. The manufacturing method for the solid-state imaging device according to claim 6, wherein
the second interlayer insulating film forms a plurality of layers which comprise a first silicon oxide film, a first silicon nitride film formed on the first silicon oxide film and a second silicon oxide film formed on the first silicon nitride film.

9. The manufacturing method for the solid-state imaging device according to claim 5, further comprising:
forming a third interlayer insulating film on or above the second fixed charge film; and
forming a filter layer and a microlens on or above the third interlayer insulating film.

10. The manufacturing method for the solid-state imaging device according to claim 9, wherein
the third interlayer insulating film forms a plurality of layers which comprise a plurality of insulating films.

11. The manufacturing method for the solid-state imaging device according to claim 9, wherein
the third interlayer insulating film includes an insulating film which contains nitrogen.

12. The manufacturing method for the solid-state imaging device according to claim 10, wherein
the third interlayer insulating film forms a plurality of layers which comprise a first silicon oxide film and a first silicon nitride film formed on the first silicon oxide film.

13. The solid-state imaging device according to claim 1, wherein the second interlayer insulating film is constituted by a plurality of insulating films.

14. The solid-state imaging device according to claim 13, wherein
the second interlayer insulating film is constituted by a first silicon oxide film, a first silicon nitride film formed on the first silicon oxide film and a second silicon oxide film formed on the first silicon nitride film.

15. The solid-state imaging device according to claim 3, wherein
the third interlayer insulating film is constituted by a plurality of insulating films.

16. The solid-state imaging device according to claim 15, wherein
the third interlayer insulating film is constituted by a first silicon oxide film and a first silicon nitride film formed on the first silicon oxide film.

17. The solid-state imaging device according to claim 1, wherein
the first and second fixed charge films are each constituted by a hafnium oxide film.

18. The solid-state imaging device according to claim 1, wherein
the first conductivity type is a P-type and the second conductivity type is an N-type.

19. The solid-state imaging device according to claim 1, wherein
the first conductivity type is an N-type and the second conductivity type is a P-type.
